(19) United States
(12) Patent Application Publication
(10) Pub. No.: US 2024/0263352 A1
(43) Pub. Date: Aug. 8, 2024

(54) CONTROLLED NANOMATERIAL MANUFACTURING

(71) Applicant: CVD Equipment Corporation, Central Islip, NY (US)

(72) Inventors: Karlheinz Strobl, Mt. Sinai, NY (US); Emmanuel Lakios, Mt. Sinai, NY (US)

(21) Appl. No.: 18/568,096

(22) PCT Filed: Jun. 10, 2022
(86) PCT No.: PCT/US2022/032965

§ 371 Date: Dec. 7, 2023

Related U.S. Application Data
(60) Provisional application No. 63/209,640, filed on Jun. 11, 2021.

(51) Int. Cl. C30B 35/00; B01J 21/06; B01J 21/18; B01J 23/52; B01J 23/72; B01J 35/45; B01J 37/02; C30B 25/00; C30B 29/02; C30B 29/06; C30B 29/60; C30B 29/62

(52) U.S. Cl. CPC C30B 35/00; B01J 21/06; B01J 21/185; B01J 23/52; B01J 23/72; B01J 35/45; B01J 37/0215; C30B 25/005; C30B 29/02; C30B 29/06; C30B 29/602; C30B 29/62

(57) ABSTRACT

An internal gas heating system apparatus enables operation of a large diameter horizontal chemical vapor processing tube reactor in the manufacture of nanomaterials, such as silicon nanowires (SiNWs) or vertically aligned carbon nanotubes on at least one catalytically active substrate. Where the nanomaterials are SiNWs, they may have controlled length, dopant level incorporation, and lower and narrower diameter distribution that on average is not greater than 50% of the average catalytic Au nanoparticle size deposited on the catalytically active substrate(s) before the SiNW growth phase.

### CROSS-REFERENCE TO RELATED APPLICATIONS

This application is a 371 National Stage Application of International Application No. PCT/US2022/032965, filed Jun. 10, 2022, which claims the benefit of, and priority to, U.S. Provisional Patent Application No. 63/209,640 filed on Jun. 11, 2021, the entire contents of which are hereby incorporated herein by reference.

### TECHNICAL FIELD

This disclosure is directed in general to apparatus and methods for growing nanomaterials on catalytically active substrates. In particular, this disclosure is directed to growing harvestable silicon nanowires (SiNWs) for high sensitivity sensor manufacturing and other NW-FET (nanowire field-effect transistor) applications, and vertically aligned arrays of carbon nanotubes (CNTs) on catalytically active substrates.

### BACKGROUND

SiNWs or CNTs having an average diameter d and length L can be manufactured with small diameter process tubes with prior art technology with chemical vapor deposition (CVD) horizontal tube reactors on small area catalytic Si wafers that are covered with substantially spatially isolated gold (Au) or other types of nanoparticles (NPs) having an average diameter D or are covered with a thin catalytically active metal film of gold (Au), iron (Fe), copper (Cu), or other metals or metal alloys.

While the prior art discusses how to make such doped SiNWs on smaller substrates for small diameter (1 inch) process tubes, they do not discuss how to manufacture similar SiNWs on large area Si NW catalytic substrates, for example, Si wafers with 4 inch diameter, and/or on multiple such larger area SiNW catalytic substrates simultaneously. To make such disposable highly specific and sensitive sensor devices economically viable, it is desirable to manufacture the desired SiNW types as economically as possible and in as narrow a diameter distribution range as possible.

It would be desirable to grow the SiNWs simultaneously on multiple larger-size catalytic substrates in the same batch run while achieving a similar type of SiNW growth on all active SiNW catalytic substrate surface areas.

It would also be desirable to grow vertically aligned CNTs on flat catalytically active substrates (e.g., silicon (Si) wafers or metal foil) over extended spatial areas, whether such substrates are oriented horizontally or vertically (e.g., hanging metal foils) and stacked parallel to each other to increase the production quantity of CNTs or other nanomaterial grown on the substrates.

### SUMMARY

When SiNWs are separated (harvested) from the SiNW growth substrates and used, for example, as NW-FET sensors, it may be desirable for high sensor detection sensitivity to obtain a narrow diameter distribution of the SiNWs that, for example, have an average diameter d<30 nm or d≤1.5*D, that have an average length L>5 μm when using Au NPs having an average diameter of 20 nm. In addition, it may be desirable to be able to grow SiNWs simultaneously in a single batch CVD process on a catalytic substrate wafer (wafer covered with substantially spatially isolated Au NPs at a surface density of about 0.1-100/μm²), in a single batch CVD process run that has a larger surface area, for example, a 4 inch or larger diameter SiNW catalytic Si wafers.

The present disclosure is directed to the manufacture and design of chemical vapor processing reactors that may include gas preheaters and/or gas heating round-to-rectangular flow converters (e.g., in the form of a single or a double H-bridge), which, when used in combination with the presently disclosed processes, enhance the growth of nanomaterials. In embodiments, SiNWs with diameter d≤1.5*D are grown with sufficient control of surface area density, an average length L, and/or dopant incorporation and can be used to manufacture harvestable SiNWs having an average resistance of R=0.01-100 MΩ, or R=0.1-20 MΩ or R=1-5 MΩ on at least one large catalytic SiNW growth substrate having catalytic NPs with an average diameter D in a larger size (e.g., >4-inch inner diameter) process tube. With prior art technology, i.e., without such a gas preheater and/or H-bridge, similar diameter SiNW can only be manufactured with smaller size process tubes, for example, with inner diameter (ID)≈1-3 inches and appropriate smaller size SiNW catalytic growth substrates in standard prior art SiNW process growth condition region. For larger size process tubes, for example with ID≈5-6 inches, when the presently described process growth conditions are used without the addition of a gas preheater and/or H-bridge, or when the conventional growth conditions are used with the gas heater and/or H-bridge, unsatisfactory SiNW growth is obtained.

In particular, the addition of the gas preheater and an H-bridge into a larger size process tube, for example with ID≥4 inches, allows operation of a nanomaterial growth process at lower process temperature, lower process pressure, and less total gas flow rate than prior art process flow scale-up teaches. In embodiments, the presently disclosed processes do not compromise the SiNW density, length, or diameter and, in general, will provide an overall lower distribution of these parameters because using the combination of innovative steps described herein, premature deactivation of the catalytic active NPs that grow the SiNWs with a vapor-liquid-solid (VLS) CVD method is reduced. In other embodiments, the growth uniformity of vertically aligned CNTs is enhanced in uniformity and spatial area when the catalytic substrates are surrounded by a horizontally or vertically oriented H-bridge.

In embodiments, the presently described systems and methods may allow the growth of harvestable SiNW having a sufficiently high surface area density on a large area, for example, 4 inch or larger SiNW catalytic wafer (for example, isolated Au NP-covered Si wafers) that simultaneously also have a narrow average SiNW diameter with a narrow diameter distribution, sufficient length to cover the distance between the two electrical sensor pads that get electrically connected to harvested, suitable functionalized and deposited SiNWs, and that these SiNW have a suitable resistance and/or doping range and resistance and/or doping distribution to allow to make sufficient high yield SiNW based sensor devices, and to be able to independently able control these parameters to fit the target needs of a chosen application.

In other embodiments, the presently described systems and methods may achieve suitable dopant control while the diameter d of the SiNW is d≤1.5*D and with an average L≥5 μm, with D being the diameter of the average catalytic NPs used to manufacture a catalytic substrate.

In yet other embodiments, the presently described systems and methods may achieve SiNWs with an average length L≈10 μm or greater for high yield functionalized NW-FET device manufacturing having a source to drain distance l≈1-20 μm, or in general, have an average length L≥1 μm.

In further embodiments, the presently described systems and methods may allow the growth of nanomaterials simultaneously on multiple catalytically active substrates, for example, 2, 3, 4, 6, or 8 wafers which may have a round or square shape, and which may have a 4-inch diameter or width and length dimension, or one or more 3″×3″, 4″×4″, 6×6″, or 8×8″ or larger substrates along the process tube and/or parallel to each other.

In embodiments, the presently described systems and methods may allow the growth of nanomaterials simultaneously on two catalytic substrates that are stacked or positioned back-to-back to each other with their catalytic surface, not in contact with each other.

In other embodiments, the presently described systems and methods may allow the utilization of lower diameter Au or other type of NPs, for example, with D≤5-100 nm or D≤25 nm, to make SiNW while still achieving a minimal targeted length L, minimal surface density useable for SiNW harvesting, and targeted dopant incorporation.

In yet other aspects, the presently described systems and methods may provide SiNWs that have a diameter d≈20 nm while still being suitably doped so that they have a resistivity R of for example R=0.01-50 MΩ, or R=0.1-10 MΩ and a length L≥2 μm, L≥5 μm, L≈10 μm, or L≥10 μm, and have sufficient surface density to make SiNW harvesting practical for functionalized NW-FET manufacturing.

### BRIEF DESCRIPTION OF THE DRAWINGS

The above and other aspects, features, and advantages of the present apparatus and CVD nanomaterial growth processes will become more apparent in light of the following detailed description when taken in conjunction with the accompanying drawings in which:

FIG. 1 and FIG. 2 schematically depict a cross-sectional view of two different prior art nanomaterial growth systems having a stationary furnace.

FIGS. 3A and 3B schematically depict a cross-sectional view of multiple embodiments of nanomaterial growth systems in accordance with the present disclosure.

FIG. 3C schematically depicts a perspective view of another exemplary embodiment of a nanomaterial growth system in accordance with the present disclosure and FIG. 3D schematically depicts a perspective view of a round-to-rectangular flow converter useful in the system of FIG. 3C in accordance with an embodiment of the present disclosure.

FIG. 4A shows a front view of a prior art thermal baffle for a rolling furnace nanomaterial growth system.

FIG. 4B-4F shows a front view for gas transmissive thermal baffles for a nanomaterial growth system in accordance with the present disclosure.

FIG. 4G shows a front view for gas transmissive thermal baffle suitable for use in making the round-to-rectangular flow converter of FIG. 3D.

FIGS. 5A and 5B show schematically the front or back view of selected embodiments of a single and a dual H-bridge configuration in accordance with the present disclosure.

FIG. 5C schematically illustrates a collection of vertically-oriented foil substrates which may be processed in chemical vapor processing reactors in accordance with the present disclosure.

FIGS. 6A and 6B show a top SEM view of an undoped and doped SiNW growth wafer manufactured with 30 min growth time at 410° C., 700 mTorr, and with 100% cross-sectional area scaled process gas flows, with and without B₂H₆ as dopant gas using the nanomaterial growth system with a 75 mm inner process tube diameter of EXAMPLE 1.

FIG. 7 shows a top SEM view of an undoped SiNW growth wafer manufactured similarly to FIG. 6A using a scaled prior art nanomaterial growth system with 100% cross-sectional area scaled process gas flows with a 150 mm inner process tube diameter of EXAMPLE 1.

FIG. 8 shows a top SEM view of an undoped SiNW growth wafer grown at the same process parameters as FIG. 7, but with a nanomaterial growth system also incorporating a gas preheater and a single H-bridge in accordance with the present disclosure.

FIG. 9A shows a top SEM view of undoped SiNW growth density grown with the same system as used for FIG. 8, but at different and lower process conditions, in accordance with other aspects of the present disclosure.

FIG. 9B shows a top SEM view of doped SiNW growth density grown with the same system as for FIG. 9A, but with the inclusion of B₂H₆ as a dopant source.

FIG. 10 shows the SiNW diameter variation and standard deviation 410° C. and 380° C. versus the dopant concentration change for a nanomaterial growth system and other process conditions as used for FIG. 8 or 9B.

### DETAILED DESCRIPTION

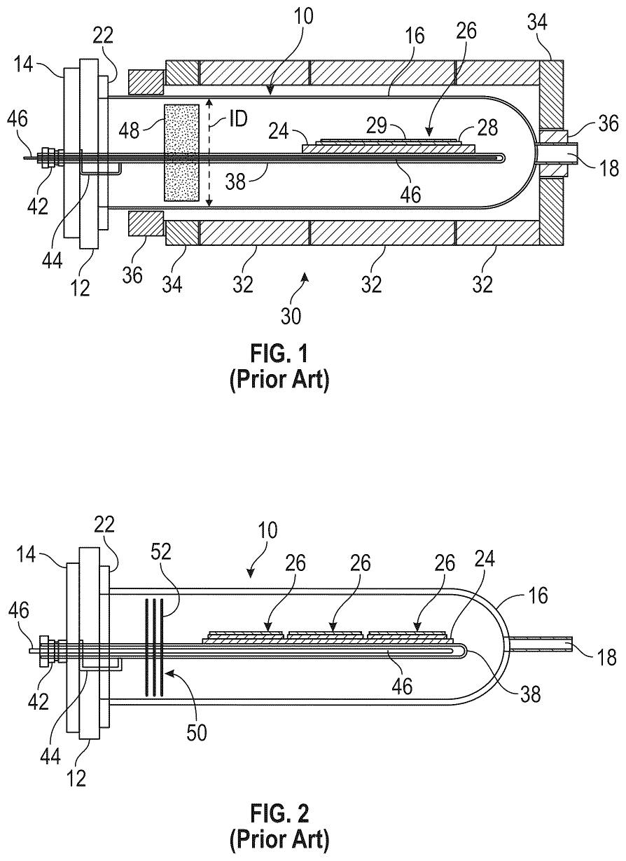

FIG. 1 shows components of one type of a prior art CVD horizontal tube furnace system used for growing harvestable SiNW or other nanomaterials (e.g., CNTs) on a catalytically active substrate wafer, which includes a heated process chamber 10. Chamber 10 includes a gas ring 12, an end cap 14, and an asymmetric process tube 16 with a narrowed-down neck exhaust gas port 18 on one side and a flange 22 on the other side. Chamber 10 is formed by a sealed arrangement (i.e., with O-rings and cooling to protect the seals) of gas ring 12, the process tube 16, end cap 14. As needed, respective gas entry ports and optional pressure sensing (not shown in FIG. 1) are present in either the gas ring 12 or endcap 14. The process tube 16 is surrounded (at least during a CVD nanomaterial growth processing step) by a stationary resistive or infrared heater 30, for example, a clamshell oven, which can have multiple individually controllable heating zones 32, insulating the end zones 34, and optionally flexible and removable insulating means 36, i.e., flexible insulating collars made from quartz fibers or ceramic wool, between the oven end zones 34 and the process tube 16.

Various systems/methods (not shown) are used in prior art systems for injecting and distributing one or more process gases into the chamber 10. Inside chamber 10 a substrate holder 24 is used to locate and support a catalytically active substrate 26 for SiNW or other nanomaterial growth via a vapor-solid-liquid (VLS) chemical vapor deposition (CVD) growth process. The substrate 26 includes a support substrate 28 that has at least a partial areal coverage of a nanomaterial growth layer 29. For example, layer 29 can contain a very thin gold (Au) film (typically on the order of nanometers to tens of nanometers), include a substantially spatially isolated random distribution of Au nanoparticles (NPs) that are partially adhered to the substrate 28, for example having an average diameter d≈20 nm, or include a thin film layer stack made of 20 nm SiO₂, 10 nm Al₂O₃, or 0.8 nm Fe.

FIG. 1 shows a particular embodiment of the prior art where the substrate holder 24 is secured to a transfer arm 38 that is held and connected to the end cap 14 through a seal 42 and is additionally mechanically supported with a bracket 44. Arm 38 is also shown to be hollow on the inside and to hold multiple thermocouples 46 terminated at different distances from the end cap that can be used to control matching multiple heating zones 32, respectively. An optional thermal shield 48, sometimes also called a thermal plug, is shown in FIG. 1 in the form of one sealed hollow evacuated quartz cylinder that has been filled with quartz fiber wool to provide a radiation leakage shield for the process tube 16 outside the heated zone of the furnace towards the direction of the metal endcap 14. Shield 48 helps to reduce the heat loss from the heated section of the process tube towards the gas ring 12 and end cap 14 and provides therefore a larger substantially temperature uniform SiNW processing region downstream of them.

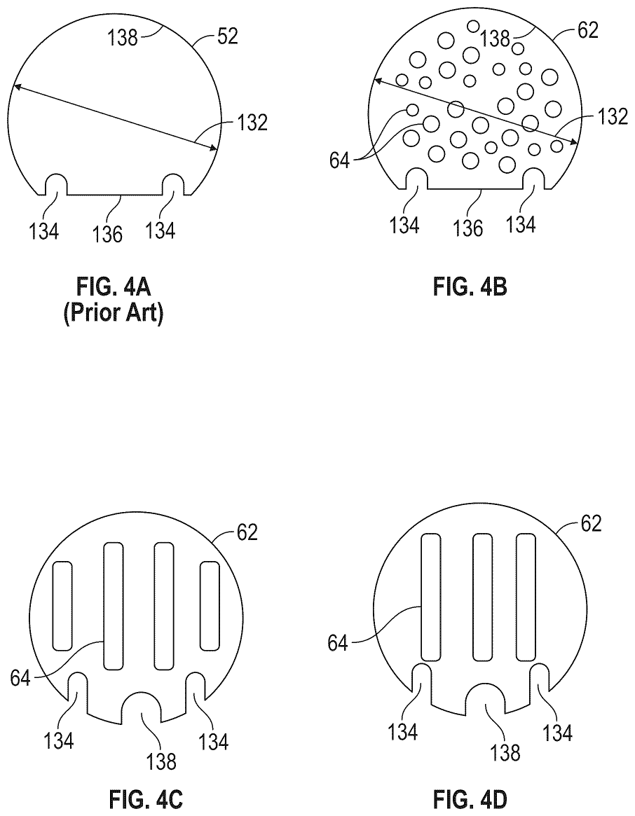

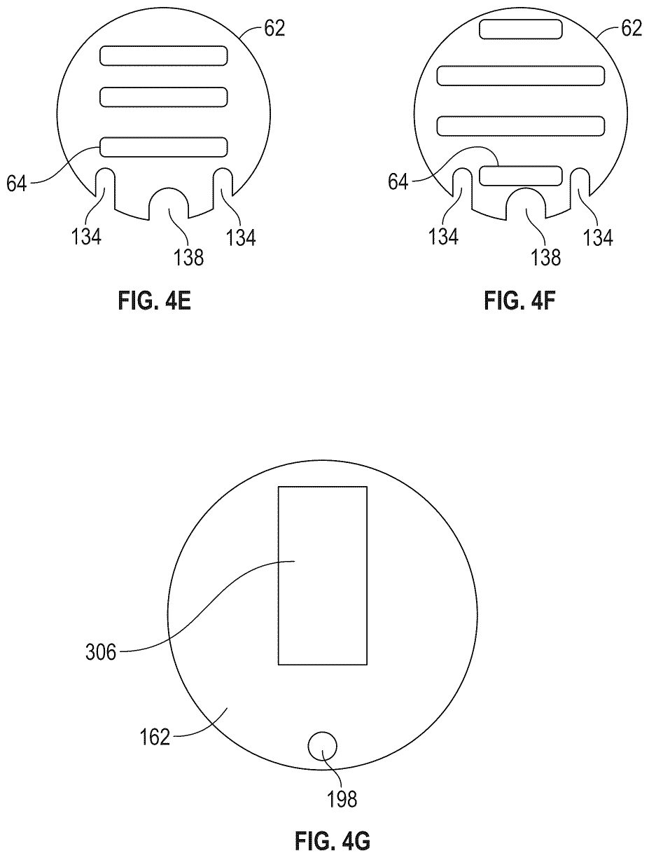

FIG. 2 shows another system including a scaled-up chamber 10 with a process tube 16 for a stationary furnace that has a working zone long enough to hold three SiNW catalytically active substrates 26. Instead of the thermal shield 48 shown in FIG. 1, a thermal shield 50 is shown that includes multiple substantially identical thermal baffles 52 e.g., light scattering white quartz disks, to provide a radiation leakage shield for the process tube 16 outside the heated zone of the furnace towards the direction of the metal endcap 14. Thermal shield 50 is built to be non-gas-transmissive so that any process gas must travel around them (e.g., between their outer edge or edges and the inner wall of the process tube 16) to reach the working zone of the chamber 10. One or more partial length vertical slots that may be cut into the baffles 52 below a respective support arm. The slots may be slightly wider than the width of the respective arm 38, for example, to facilitate their quick removal for maintenance (see FIG. 4) or for the avoidance of other parts located inside a process tube 16.

A mixture of process gases (not shown in FIG. 1 or 2) enters through a port in the gas ring 12 or endcap 14 into the process tube 16, then moves around the outside of any available radiation shield 48 or 50 in an annular ring, and then exit the process tube 16 through the exit gas port 18, after flowing over the catalytically active substrates 26. The only hot surfaces accessible to process gases in this prior art chamber 10 are the inside of the process tube between the inner wall of the radiation shield 48 or 50 and the exhaust port 18, and the support arm 38 and substrate support 24.

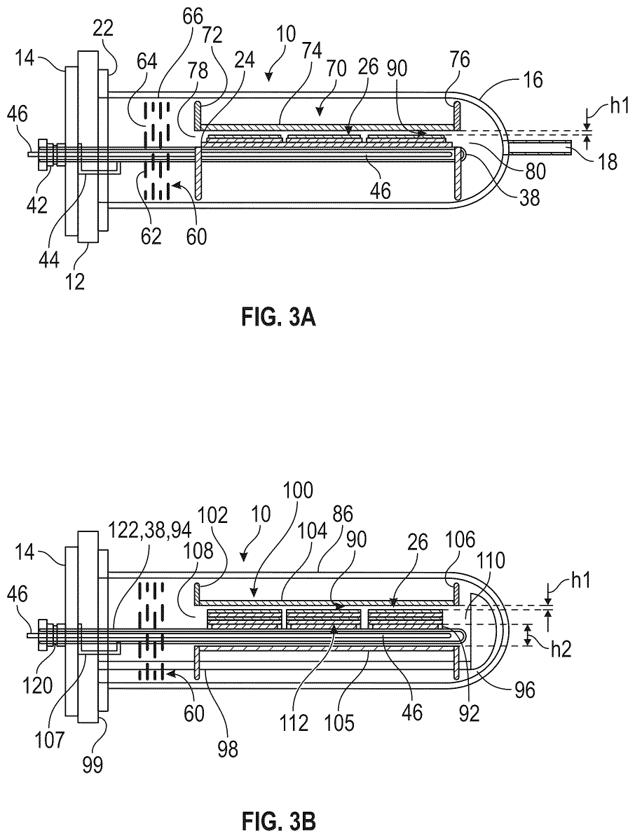

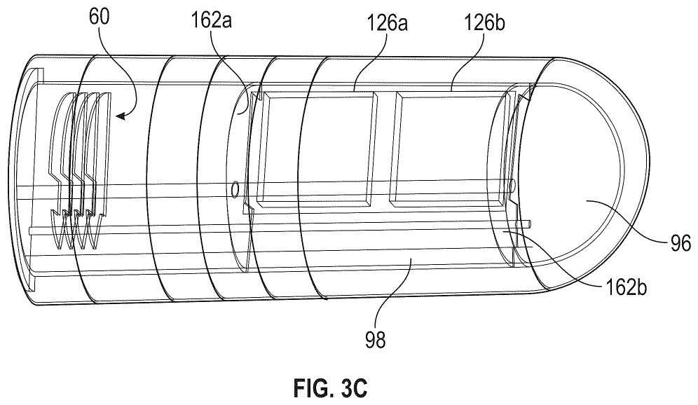

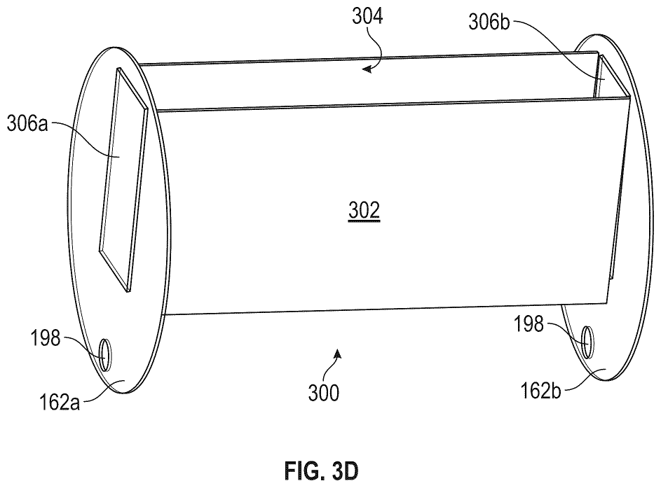

FIG. 3A shows a first partial embodiment of a system in accordance with the present disclosure for a nanomaterial growth system having a stationary oven where the prior art non-gas transmissive thermal shields 48 or 50 are replaced with an internal process gas preheater 60 with a tortuous gas transmission path that includes a group of intentional gas transmissive and partially thermal radiation leaking vertical baffles 62 that are spaced apart to form a spatial gap between adjacent baffles 62. Each such baffle 62 has at least one internal cutout 64 for gas transmission that allows process gas and heat radiation to enter the gap 66 between two adjacent baffles and to heat the neighboring baffle 62 closer to the endcap 14. Neighboring baffles 62 have offset cutouts 64 to result in a tortuous gas flow path through them and reduced radiation leakages thereby causing all the process gas that is not flowing around the preheater 60 to go through it in a tortuous pathway while it is getting heated from collisions with the increasingly hotter and hotter quartz baffles 62. The bigger the total area of all cutouts 64 are for each baffle 62, the lower is its flow resistance and the less process gas escapes around the preheater 60, and thereby more of the process gas gets preheated. All these cutouts 64 cause some radiation leak to the next baffle, so that overall, more baffles 62 are needed to achieve in total similar thermal isolation between the hot and cold part of the process tube 16. Because of these intentionally created radiation leak paths, the thermal isolation is now more spatially spread out and colder gas gets warmed up by first hitting the hotter baffle walls opposite to each gas port before it escapes to the next baffles though the cutouts 64 in each baffle 62. Ideally, the respective size and area of the cutouts 64 as well as their location, distribution, and the spacing 66 between adjacent baffles 62 is designed such that the radiation loss through a direct line of sight through these gas preheaters 60 is reduced, so that, in combination, the gas residence time inside the gas preheater 60 is increased to achieve at least a first level of substantially uniform process gas preheating.

In one embodiment, such baffles are made from opaque or partially opaque quartz plates (for higher radiation leakage) with selective area removed in each baffle 62. In an embodiment, different types of materials are used for each baffle 62, for example, a more heat transmissive material toward the inside and a less heat transmissive material towards the outside, i.e., endcap 14 direction. In embodiments, all baffles 62 are made from quartz, graphite, or metal material that is sufficiently non-reactive to the process gases.

FIG. 3A shows another partial embodiment of a system in accordance with this disclosure in the form of an optional fully or partially removable H-bridge 70 that functions as a round-to-rectangular flow converter and as a gas heater. The H-bridge 70 includes a first bridge support 72, sometimes also called herein gas inlet port 72, one or more elements together forming a horizontal top bridge 74, and a second bridge support 76, sometimes also called herein gas outlet port 76. In embodiments, the H-bridge 70 parts are made from clear, semi-transmissive, or opaque quartz sheets. In one embodiment, the H-bridge 70 includes components 72, 74, and 76 that are connected, for example, fused or connected with removable pins, near their contact points, and the support 72 and 74 mechanically interact with at least one support arm 38 by gravity and the respective arm 38 has suitable features for locating it in a defined place along the arm 38. Optionally, in an embodiment, there is an easy way to remove the H-bridge 70 as a single unit and to place it back in a substantially identical spatial location, for example, defined with suitable spatial locators secured on arm 38. In another embodiment, the H-bridge 70 is made of at least two or three isolated parts and each part is being supported suitably and located through features that mechanically interact with at least one support arm 38 so that there is only a small gap between two adjacent parts, for example, less than 10 mm, 5 mm or 3 mm between them and each component 72, 74 or 76 has suitable features for locating each separate part or part group in space separately to another part or part group, together forming an H-bridge 70. If at least one arm 38 is used, it has matching support and/or locating features that make it easy to remove one or more of them and place them back in a substantially identical spatial location.

In embodiments, the process tube 16 is large, and at least two support arms 38 are being used. For example, a process tube 16, with ID=150 mm with a 300 mm usable working zone allows to position up to three, 4-inch diameter catalytically active substrates (e.g., wafers, foils or mesh structures) in a row in the gas flow direction. Two quartz or alumina tubes or rods, for example, 10-25 mm thick, can be used to make the arms 38 that support the weight and location of all the parts mounted on the cantilevered arms 38.

Making this H-bridge 70 removable is not necessary to implement the teaching of this disclosure but makes it much easy/faster for loading and removing one or more substrates 26 onto a support tray 24 that is located and supported by the arm 38 before and after a nanomaterial growth batch run. In an alternative embodiment, the substrates 26 are placed and removed to and from underneath the horizontal bridge 74. In another embodiment, the catalytically active substrates 26 are hung from a holder, and in another embodiment, multiple such substrates are hung parallel to each other with a pre-determined gap between them, for example 2 mm, 4 mm, 6 mm or 10 mm or larger. The catalytically active substrate 26 includes a support substrate 28 that has at least a partial areal coverage of a nanomaterial growth layer 29, such as, for example, gold (Au, copper, copper oxide, iron, or other catalytic material within the purview of one skilled in the art) in the form, e.g., of a film (typically on the order of nanometers to tens of nanometers), or as spatially isolated, randomly distributed nanoparticles.

The first gas input port 72 has an opening 78 with height h through which process gas enters a substantially rectangular volume 90 with height h formed by the inner surface of the bridge 74, the substrate holder 24, and the inner walls of the process tube 16. The gas output port 76 has an opening 80 through which exhausted process gas escapes towards the process tube exhaust port 18 from volume 90.

FIG. 3B shows multiple other partial embodiments of chemical vapor processing reactors in accordance with this disclosure with an end-sealed process tube 86 suitable for a movable furnace, for example, a rolling furnace with process tube 86 housing up to three back-to-back oriented (the two growth surfaces point away from each other) substrates 26 in a horizontal sequential alignment that are being supported by three, four (less gas turbulence generation), or more standoff fingers 92 without the use of substrate support 24. Not shown in FIG. 3B are partial loading of this wafer mounting solution where one to five of the substrates 26 shown in FIG. 3B are absent and where at least some of the bottom substrates 26 shown in FIG. 3B are replaced by regular Si wafers of the same size or by a substrate holder 24 that sits on top of the finger 92 or has suitable cutouts to mechanically interconnect with them. In embodiments, either a single arm 38 or two arms 94 are used to support all the parts inside the process tube 86, except the exhaust gas collector 96 and the optional removable exhaust gas line 98 that optionally rests on the bottom of the process tube 86 and connects through the gas ring 99, for example with an elbow and an O-ring seal, to a suitable exhaust gas line (not shown in FIG. 3B) connected to a suitable vacuum pump system.

Also shown in FIG. 3B is an alternative partial embodiment of this disclosure in the form of a double H-bridge 100 that functions substantially as a round-to-rectangular flow converter and as a multi-surface gas heater. This double H-bridge 100 includes a first bridge support 102, sometimes herein also called gas inlet port 102, one or more components that together form a horizontal top bridge 104, one or more components that together form a horizontal bottom bridge 105, and a second bridge support, sometimes herein also called gas outlet port 106. The gas input port 102 has an approximately rectangular opening 108 with height h≈h1+h2+2*height of substrates 26 through which process gas enters a substantially rectangular volume 90 and volume 112 formed by the inside surface of the top and bottom bridge 104 and 105, the inner wall of the process tube 86 and the row of substrates 26 and/or replacement wafers and/or substrate support 24 as discussed above. The gas output port 106 has an opening 110 through which exhausted process gas escapes from volume 90 and 112 and gets collected by an exhaust gas collector 96 that is connected to a process tube 86 internal exhaust line 98. Volume 90 has an approximate height h1 and volume 112 has an approximate height h2. The gas flow entering the gas input port 102 gets split by a row of substrates 26, and/or dummy Si wafers, or a support substrate 24 (not shown in FIG. 3B) into the two quasi separate nearly laminar gas flow paths, one for each volume 90 and 112.

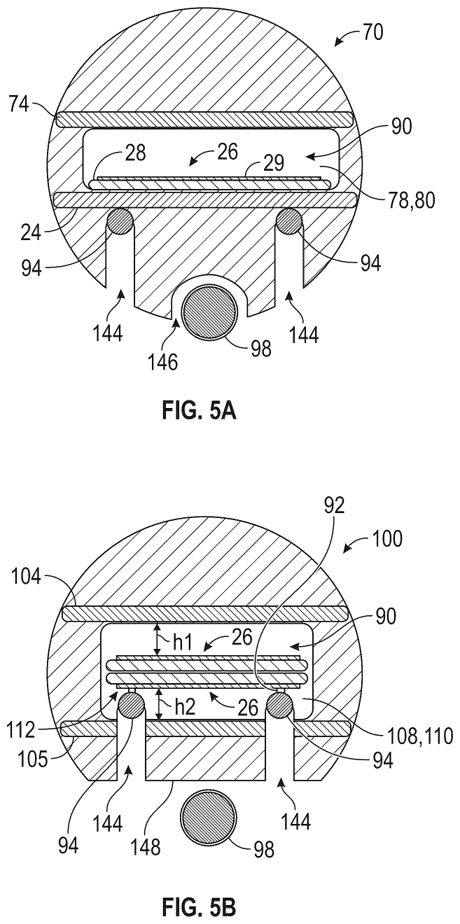

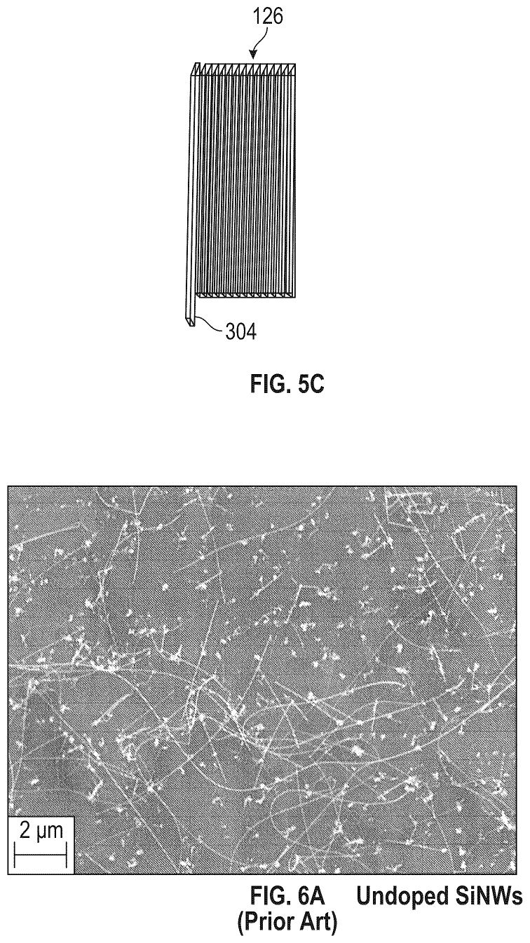

FIG. 3C is an alternative embodiment of a nanomaterial growth system which is similar to the embodiments shown in FIGS. 3A and 3B in that it also includes a round-to-rectangular flow converter, however instead of a single or double H-bridge defining a horizontally-oriented rectangular opening, the flow converter 300 includes two baffles 162a, 162b joined together by two planar walls 302, 304 (see FIG. 3D). It should be understood that the embodiment of FIG. 3C may include a preheater 60 as shown, or the preheater may be eliminated. As seen in FIG. 3D, each baffle 162a, 162b includes an opening 198 through which exhaust gas line 98 can pass, and a vertically-oriented rectangular opening 306a, 306b. Vertically-oriented rectangular openings 306a, 306b are aligned with each other and generally correspond in dimension to the dimension of a collection of vertically-oriented substrates 126 (e.g., hanging metal foils; see FIG. 5C) which are stacked parallel to each other to increase the production quantity of CNTs or other nanomaterial grown on the substrates. In the embodiment of FIG. 3C, two collections of vertically-oriented substrates 126a, 126b are shown, although more or less than two collections of vertically-oriented substrates may be present. Flow converter 300 also improves heat distribution over hanging foil substrates 126a, 126b, thus improving the uniformity of growth of the nanomaterials. The presence of flow converter 300 can reduce the non-uniformity of heating substrates 126a, 126b by sixty-five percent or more (e.g., temperature variations of about 30° C. can be reduced to about 10° C.), in embodiments by 75 percent or more (e.g., temperature variations of about 20° C. can be reduced to about 4° C.), compared to a system that does not include flow converter 300. The uniformity of temperature to which the substrates 126a, 126b are exposed makes the embodiment of FIG. 3C particularly well-suited for the growth of carbon nanotubes.

It should be understood that the present chemical vapor processing reactors can be employed for chemical vapor deposition (CVD) processes to deposit materials onto a surface (e.g., onto any solid substrate), or for chemical vapor infiltration (CVI) processes to deposit materials onto and within any three-dimensional porous substrate (e.g., mesh structures). It is also contemplated that the present chemical vapor processing reactors can be employed for both CVD and CVI processes, such as, for example, where a CVD process is used to grow vertically aligned arrays of CNTs on a foil or other solid substrate, and then a CVI process is used to deposit materials between and amongst the vertically aligned arrays of CNTs that were formed in the same chemical vapor processing reactor.

In embodiments, the process tube 16 is large and more than one support arm 94 is being used. For example, for a process tube, 16 with ID=150 mm with a 300 mm usable working zone for up to three 100 mm diameter substrates 26, or up to three back-to-back paired substrates 26 positioned in a row in the gas flow direction, or at least some of these substrates 26 are replaced by regular Si wafers acting as support for substrates 26 or portions thereof (for example a one-half or one quarter 4 inch wafer). In embodiments, two quartz or alumina tubes are used as arms 94 instead of one to support the weight and location of all the parts mounted on the cantilevered arms 94 supported by a suitable adjustable bracket 107.

In one embodiment, the outer dimensions of the input and output ports 72 and 76 or 102 and 106 are similar to the dimension of any radiation shield 48 or 50 or gas preheater 60 located upstream to the H-bridge 70 or dual H-bridge 100. In one embodiment, the radiation shield used inside a process tube near the insulating heater zone 34 is a preheater 60 and the gas transmitted through the preheater 60 is substantially diverted into an input port 78 or 108 and process gas flowing through the gap of the inner wall of the process tube 16 and around the gas heater 60 is substantially not entering said input port 78 or 108 or volumes 90 and/or 112 and repelled by the outside surface of the horizontal bridge 74 and substrate holder 24 or the horizontal top bridge 104 and bottom bridge 105 and then escapes between the outside of the output port 76 or 106 and the inner wall of the process tube 16 towards the exit port 18 or exhaust gas collection port 96. In one embodiment, the two input and output ports 72 and 76 or 102 and 106 increase the resistance to process gas flowing outside of volume 90 or volumes 90 and 112 thereby allowing a significant portion of the available process gas flow through volume 90 or volumes 90 and 112. In one embodiment, the width of the bridge 74 and/or 105 is at least the width of the substrates 26. In one embodiment, the width of the opening 78 and 80 is substantially similar or bigger than the width of the substrates 26. In one embodiment, the height of the opening 78 and 80 or 108 and 110 is substantially similar to the distance between the substrate holder 24 or substrates 26 and the inner surface of the bridge 74 or the distance between the top and bottom bridge 74 and 105.

In embodiments, a single H-bridge 70 or dual H-bridge 100 is used without a gas preheater 60. In such embodiments, there is a sufficient gap between the inner side of any thermal plug 48 or thermal baffles 52 used and the support 72 or 102 for process gas flowing around a plug 48 or baffles 52 to at least partially flow into the volume 90 or volumes 90 and 112. In one embodiment, primarily preheated progress gas from a preheater 60 enters volume 90 or volumes 90 and 112, while the non-preheated process gas that passes around the outer edges of the preheater 60 is less likely to enter volume 90 or volumes 90 and 112.

In one embodiment, the inner surface of bridge 74 and the substrate holder 24 or the inner surface of the bridge 104 and 105 and present substrates 26, and/or Si wafers acting as substrate holder and/or substrate holder 24 are heated by the radiation from the oven surrounding a process tube 16 or 86. Heat from the oven enters the process tube 16 or 86 thereby heating by convection and radiation absorption at least the direct line of sight surface of the present parts (e.g., the direct line of sight surfaces of horizontal bridge 74, substrate support 24 regular Si wafers acting as substrate holder substitute, horizontal top bridge 104, and horizontal bottom bridge 105), and thereby also the inner surfaces of volume 90, or volumes 90 and 112 through partial radiation transmission, re-radiation and thermal conductance through the material forming such parts. This serves as a secondary gas heater for process gas flowing through volume 90 or volumes 90 and 112, thereby making the overall process gas temperature distribution inside the volume 90 or volume 90 and 112 more spatially uniform.

In embodiments, the height h1 or h2 of the volume 90 or 112 is in the range of 5-100 mm, 10-50 mm, or 20-40 mm. In embodiments, the ratio of substrate 26 width perpendicular to the gas flow direction to volume height h1 or h2 is in the range of 0.05-1, 0.1-0.5, or 0.2-0.4.

In embodiments, it is envisioned that the shape of the ports 72 and 76 or 102 and 106 may be a flat sheet, a concave shape, a spherical shape, a truncated conical shape, a combination and/or variation thereof. In embodiments, it is envisioned that the bridge 74 or 105 may be a horizontal bridge, a flat bridge with a substantially constant height, a flat bridge with a narrower height at its input side, a flat bridge with a taller height at its input side, a bridge with a non-constant height along the gas flow direction, a bridge with step height changes up and/or down along its length (for example by placing a flat middle sheet on top of a left and right short shelf), and for each case having matching input and output port heights 78 and 80 for the input and output side of the respective volume 90 and 112.

In embodiments, the group of one or more thermocouples 46 has a different feedthrough port 120 that isolates a quartz sheet 122 protecting them for exposure to process gases that is not collinearly inserted with an arm 38 or 94, but instead is located, for example on the bottom side of one arm with suitable fixturing attached to an arm 38 or 94.

In an embodiment, the height values h1 and h2 of volumes 90 and 112 are chosen to allow the most similarity between the nanomaterial growth for the top side and upside-down oriented substrates.

FIG. 4A depicts the front view of a prior art thermal baffle 52 for a rolling furnace system with process tube 82 and an internal exhaust gas line 98 in the form of a truncated circle having a diameter 132 that is smaller than the ID of the process tube 86, two cutouts 134 that are matching mechanical alignment features of two support arms 94, and a flat section 136 to avoid interference with a gas exhaust line 98 for a nanomaterial growth system with a movable furnace. The baffles 52 are cut out from a solid non-gas-permeable and light scattering material. The diameter 132 is typically 4-10 mm smaller than the inner diameter of the process tube 86 to allow insertion and mechanical movement of endcap 14 and any parts attached to the arms 94. In general, at least two baffles 62 rest on the arms 94 (typically three) and are located there through the two cutouts 132.

Typical parts 16, 18, 24, 38 or 98, and 48, 50 or 100, when present, are made from quartz and together are called a quartz ware set in this disclosure. Some of these parts are typically made from clear quartz, while at least some of baffles 52 or 62 can be made from clear, semi scattering, or highly scattering quartz material, and have either a flat or curved shape. Similar at least some supports 72, 76, 102, and/or 106, as well at least some of the bridges 74, 104, and/or 105 can be made from partially or fully opaque flat sheets or non-flat, optional concave or convex (for example for increase gas flow guidance and or resistance increase for gas flowing around them) surfaces of quartz material.

FIG. 4B shows a gas-transmissive thermal baffle 62 of this disclosure in the embodiment of a spatial arrangement of multiple cutouts 64 having the form of circular through-holes. Two different hole diameters are shown in this example, as one possible embodiment. In embodiments, any adjacent baffles 62 have their respective cutouts 64 laterally offset so that the gas flows through a stack of baffles 62 in a torturous path. In embodiments, various layouts of circular cutouts 64 are considered. In some embodiments, the cutouts 64 have a regular and in other embodiments, they have irregular spacing. In embodiments, the various cutouts 64 on the same baffle 62 have substantially similar or dissimilar diameters and/or other dimensions and/or shapes.

FIG. 4C through FIG. 4F show alternative embodiments of this disclosure in the form of a gas-transmissive thermal baffle 62 having cutouts 64 that have the shape of multiple vertical or horizontal elongated slots of different lengths and spacing. Two or more gas flow blocking cutouts 134 together with the cutout 138 provide a better gas sealing against an exhaust gas line 98 than the flat 136 section in FIG. 3B. FIG. 4D shows a matching adjacent thermal baffle 62 to the one shown in FIG. 4C, according to another implementation of this disclosure, with offset cutouts 64, shown here in the example of equal length slots.

FIG. 4C and FIG. 4D as well FIG. 4E and FIG. 4F can be adjacent thermal baffles 62 since their cutout 64 openings are spatially offset thereby requiring the process gas to flow through a stack of these pairs in a tortuous manner. Alternatively, all styles shown in FIG. 4B-4F can be mixed and matched if enough of them are being used to provide sufficient gas heating and radiation loss prevention functions. To those skilled in the art, it will follow from these teachings that other arrangements for cutouts 64 in the baffles 62 are also possible, and such variation are considered to be included in this disclosure. As seen in FIG. 4G, another baffle design, baffle 162 includes an opening 198 through which exhaust gas line 98 can pass, and a vertically-oriented rectangular opening 306 to direct process gases toward at least one vertically oriented catalytically active substrate, such as a collection of hanging foil substrates (see FIG. 5C). Baffle 162 is useful in forming flow converter 300 of FIG. 3D.

FIG. 5A shows schematically the cross-section view of one embodiment of an H-Bridge 70 near the gas input or exit port 72 or 76. Also shown is the cross-sectional profile of two matching arms 122 and an exhaust tube 98. The gas input or exit port 72 or 76 is shown as a solid disk that is cut from a flat sheet with the gas input or output port 78 or 80 shown as an approximately rectangular cutout region with a height≈h1+the thickness of substrate 26 that substantially aligns vertically with the volume 90 formed between the horizontal top bridge 74 and the top of the substrate support sheet 24 and horizontally with the substrates 26. In embodiments, the width of the ports 78 or 80 is at least slightly wider than the width of the largest substrate 26 positioned on the support sheet 24. In an embodiment, the substrate support 24 and bridge 74 extend near the edge of the gas port 72 or 76, as depicted in FIG. 5A to provide better gas flow isolation for volume 90. FIG. 5A shows an embodiment suitable for use with the embodiment shown in FIG. 3A, but with a process tube 86, an exhaust gas collection port 96, an exhaust gas line 98, and arms 94 as shown in FIG. 3B. The two cutouts 144 are used for locating the gas ports 72 and 76 on matching support arms 94 and where the round ports 72 and 76 have an additional cutout 146 to allow no interference with an exhaust line 98.

FIG. 5B shows schematically the front or back view of one embodiment of a double H-bridge 100 near the gas input or exit port 102 or 106. Also shown is the cross-sectional profile of two support arms 94 and an exhaust tube 98. In embodiments, the width of the ports 108 or 110 is at least slightly wider than the width of the widest substrate 26 with each such substrate 26 being positioned on support posts 92 that are mechanically connected to the support arms 122. In other embodiments, the width and/or height of the exit port 110 is bigger or smaller than that of the entrance port 108, for example, to achieve an improved process uniformity along the length of the process tube 86.

In one embodiment, four support posts 92 are being used to locate and support each substrate 26 near its edge in a minimal gas flow disturbing arrangement, for example, with two posts 92 aligned with the gas flow direction and located on top of the arms 94. In an embodiment, the bridges 104 and 105 extend all way near the edge of the gas port 72 or 76, as depicted in FIG. 5B to provide (together with the inner wall of the process tube 86) better gas flow isolation for the volumes 90 and 112 by substantially isolating the flow through them from all the gas flow passing outside of them. FIG. 5B shows a case suitable for use with the embodiment shown in FIG. 3B where the two cutouts 144 are used for locating the supports 102 and 106 on matching support arms 94 and where the ports 102 and 106 have a simplified D-shaped profile 148 to allow no interference with an exhaust line 98 with a simplified manufacturing process, but increasing process gas leakage, so that less from the total available process gas enters the volumes 90 and 112, thereby reducing the process gas utilization of the nanomaterial manufacturing process accordingly.

Other variations of the two basic designs discussed above in connection with FIGS. 3A and 3B and 5A and 5B will be apparent from these teachings, including modifications of these designs to for making the top bridge 100 removable for each loading and unloading of unprocessed and processed substrates 26 and are considered to be included in this disclosure.

### EXAMPLES

To further explain the teachings of this disclosure, a series of experiments are described that have either been conducted with: a prior art CVD growth system scaled to a process tube 16 or 86 having an ID of 75 or 150 mm; or a nanomaterial growth system including a chemical vapor processing reactor in accordance with aspects of the embodiments described herein.

### Example 1: 75 mm Scaled Process Tube ID

For this example, a SiNW growth process for the process gases Si₂H₆, H₂, and B₂H₆ for a straight process tube with ID1≈25 mm, a cantilevered SiNW growth system was built that contained a chamber 10 with inner diameter ID2=75 mm, as depicted in FIG. 1. A 200 mm long and 50 mm wide quartz sheet was used as respective substrate support 24 which could hold up to four 2-inch round or two half 4 inch SiNW catalyst substrates 26. To make half of a 4-inch SiNW catalyst substrates 26, a full size 4-inch wafer was cleaved in approximately two similar size half wafers.

Using this system having tube 16 with an ID=75 mm, at 10 Torr and 410° C. process temperature, only thick doped SiNW (with a diameter d≥35 nm) could be grown with an Au NP catalyst having an average NP diameter D≈20 nm. By further varying pressure, growth time, and dopant ratio of Si₂H₆/B₂H₆ while keeping the process temperature at 410° C., a much-reduced pressure, i.e. ≈0.7 Torr and no dopant flow or a dopant flow at a dopant ratio Si₂H₆/B₂H₆≈6000 allowed the growth of boron-doped SiNW during a 30 min growth time having an average diameter d≈23.5 nm+/−27% (1 standard deviation) or d≈27.5 nm+/−24% for undoped (FIG. 6A) and doped SiNW (FIG. 6A) that also had an average length L≈10 μm and SiNW density that they could be harvested and used for building functional, high sensitivity NW-FET sensors. All SiNW catalyst wafers used for all EXAMPLES listed below used Au NPs having an average diameter D 20 nm distributed at a surface density σ≈0.5-10/μm2 onto a treated 4-inch diameter Si wafer. The used SiNW catalyst substrate preparation method was conventional. It is typical for this type of SiNW growth process that the diameter and standard variation of the SiNWs depend among others on process growth temperature and dopant ratio Si₂H₆/B₂H₆, with undoped SiNW being the thinnest types for a given SiNW growth condition.

In this example, a larger diameter (75 mm) process tube, SiNWs usable for functionalized FET sensor application could be manufactured at similar process temperatures, but not without further process adjustments to pressure, flow rate, and dopant concentration.

### Example 2: 150 mm Scaled Process Tube ID

To scale the process developed in the EXAMPLE 1 series to full size 4 inch wafers with prior art technology, a larger SiNW growth system was built, similar to the one shown in FIG. 3B, with flanged and end sealed process tube 82 having an ID3=150 mm, an internal exhaust gas collector 96 and an exhaust gas line 98, and where the respective process chamber 10 was heated by a movable rolling furnace 30 having three heating zones 32 with an over 12 inch long usable working zone. On the endcap 14 two support arms 94, made from quartz tubing, were mounted that were supported by an adjustable cantilever bracket 107. As shown in FIG. 3B, each arm 94 had six standoff posts 92 for holding three single or three pairs of 4 inch diameter wafers at their edge. All examples discussed below had three regular Si wafers loaded onto posts 92 to form the bottom of volume 90 (instead of substrate support 24 shown in FIG. 3A). At least one single SiNW catalyst wafer 26 or part of such a wafer was loaded onto the first of the three substrate support Si wafers.

Instead of the gas heater, 60 shown in FIG. 3B, a scaled prior art radiation shield 50, as shown in FIG. 2, with three thermal baffles 52 in the style of 138 made from opaque quartz, as shown in FIG. 4A was used. Also, the H-bridge 70, shown in FIG. 3B, was not present for this experiment.

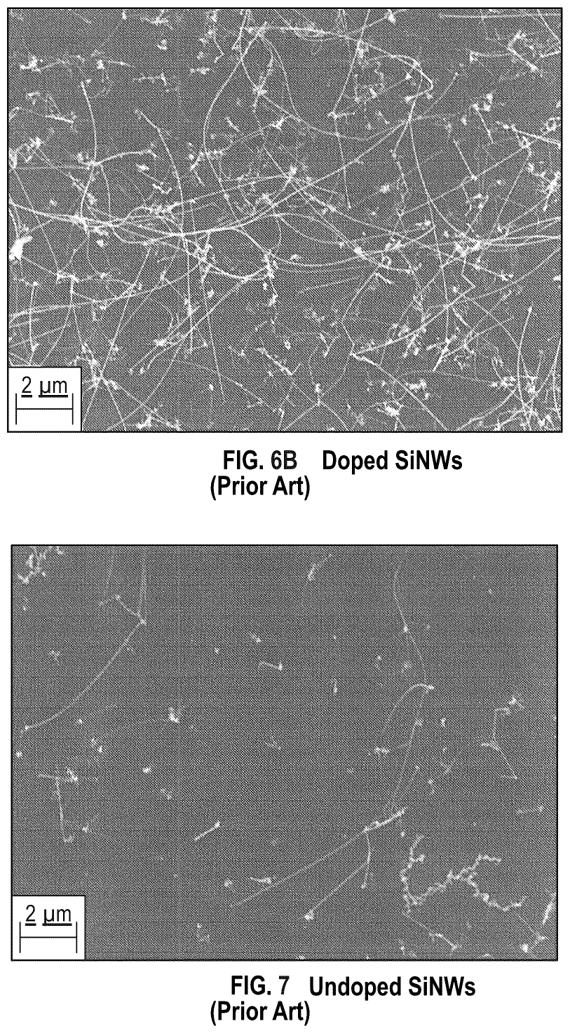

FIG. 7 shows a representative top-view SEM image of the resulting SiNW catalyst substrate 26 at either of the three Si wafer loading positions after the following prior art scaled SiNW process growth condition: 30 min growth time, 410° C. growth temperature, ≈0.7 Torr process pressure and the area scaled process flows by (ID3/ID2)2=(150/75)²=4×. The resulting average undoped SiNW diameter was ≈29 μm, i.e., much thicker than the targeted 23.5 nm achieved with the smaller diameter system from EXAMPLE 1. Since also their average length L was much shorter and the SiNW surface density was much lower, the SiNW process was no longer transferable with prior art teachings.

### Example 3: 150 mm Process Tube with Gas Heater and Single H-Bridge

To overcome the process limitations used for EXAMPLE 2, a gas heater 60 was added as shown in FIG. 3B including three baffles 62, similar to those shown in FIGS. 4C and 4D, but with a simplified, less optimum, bottom section truncated in a D shape format to avoid interference with the exhaust gas tube 98, as shown in FIGS. 4A and 4B. A single H-bridge 70 was added to the systems used for EXAMPLE 2, as shown in FIG. 3A, instead of the dual H-bridge 100 shown in FIG. 3B.

FIG. 8 shows a representative top-view SEM image of the resulting SiNW catalyst substrate 36 at either of the three Si wafer loading positions achieved with the same process growth condition as used for EXAMPLE 2. Clearly, the addition of the gas heater 60 and the H-bridge 70 improved the average length L and density of the SiNW and resulted in an undoped SiNW with an even lower average diameter d≈22 nm, i.e., better than the equivalent case shown in FIG. 6A with d≈23.5 nm. However, the surface density and average length L of the undoped SiNW were still inferior to the case shown in FIG. 6A.

### Example 4: Same as Example 3, but with Different Process Conditions

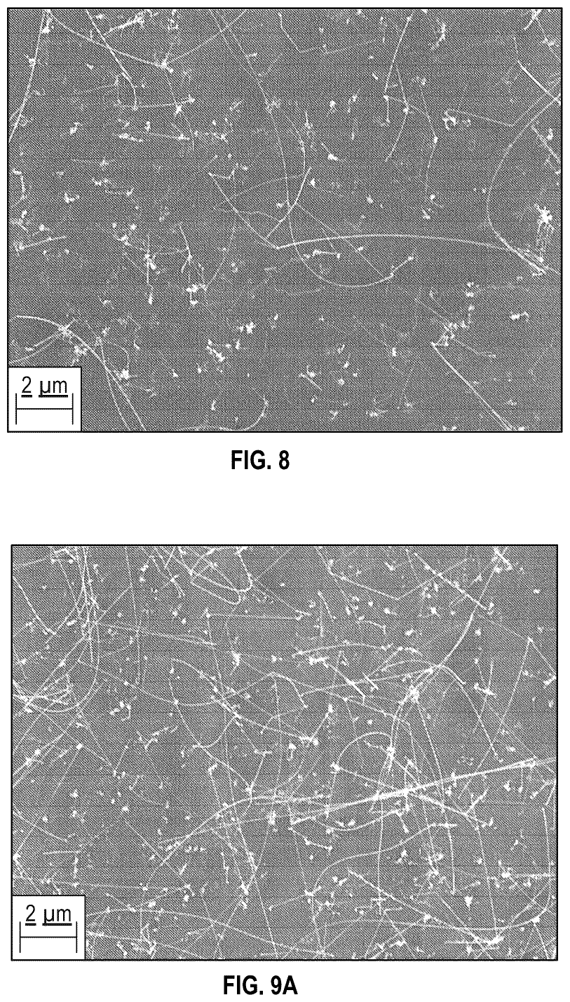

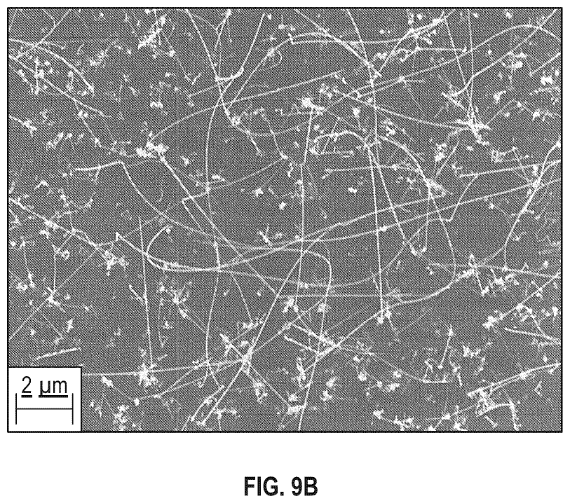

EXAMPLE 3 showed that a new process region was enabled by the addition of the gas heater 60 and H-bridge 70, which warranted further process parameter explorations. FIG. 9A shows that by further reducing all process gas flows to a 50% cross-sectional area scaled level, reducing the process pressure to 300 mTorr, and lowering the process temperature to 380° C., undoped improved SiNW growth was achieved for a 2× larger process tube 86 with d≈23.5 nm±12% that had a narrower diameter distribution and similar or better average length L and approximately similar surface density as achieved for the 2× smaller process tube system with the technology shown in FIG. 6B.

EXAMPLE 4 clearly demonstrates that the process window for the SiNW growth was significantly expanded by the addition of the gas heater 60 and single H-bridge 70. Without the addition of the gas heater 60 and H-bridge 70, only undesirable SiNW growth is possible at the same process conditions and process tube size used to achieve the results shown in FIG. 7.

### Example 5: Same as Example 4, but with Dopant Gas Added

By adding a B₂H₆ dopant gas at different flow rates, a series boron-doped SiNW was manufactured. Adding B₂H₆ gas flow at a ratio of Si₂H₆/B₂H₆≈15,000 resulted in the doped SiNW growth shown in FIG. 9B which shows a top SEM view of undoped SiNW growth wafer with an average diameter d≈27 nm, which is slightly better to doped SiNW process made with the scaled prior art system in EXAMPLE 1 (FIG. 6B), but at significantly different process parameters than prior art process scaling knowhow would suggest.

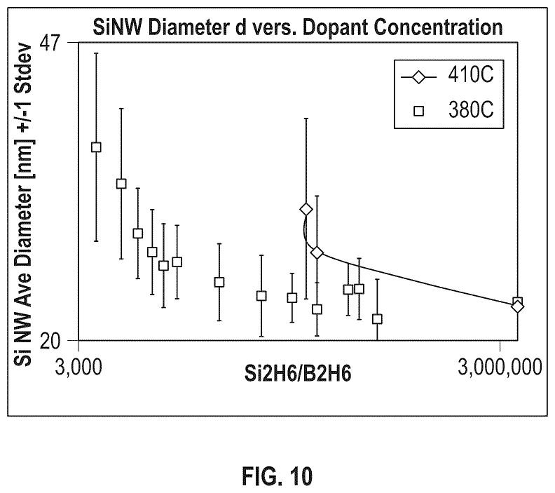

FIG. 10 shows graphically the variation in average SiNW diameter and their standard deviation for both 380° C. and 410° C. process temperature. Comparing the 410° C. and 380° C. experiments shows that for the lower process temperature the process window widened, and that for different growth temperature, different dopant gas quantity results in similar SiNW diameter. Note that the standard deviation in average SiNW diameter was reduced with the 380° C. process temperature conditions for the same doped SiNW diameter, even if undoped they looked very similar. FIGS. 9A and 9B also show a great similarity with FIGS. 6A and 6B showing that with the embodiments of this disclosure, a process scale-up was achievable for an increased chamber 10 ID which was not achievable with prior art technology without it. Changing the quartz ware alone was not enough as FIG. 8 shows. But the resulting more uniform gas temperature distribution resulted in a much wider process window under which doped SiNW could be manufactured to a targeted diameter, length, and surface area density.

Based on the above teachings, those skilled in the art will envision alternative versions of the herein discussed embodiments and design options for the gas heater 60, single H-bridge 70, dual H-bridge 100, and the above-discussed process modification that are enabled by a single or dual H-bridge and/or gas heater 60 embodiments. Similarly, without being bound to an above-discussed theory of operation, those skilled in the art can adapt the here disclosed innovations to SiH₄ or other Si-containing gas precursors, as well as to dopant precursors BH₃ or other dopant precursors useable to obtain desired SiNW doping, and/or to catalytic NP other than Au NPs usable to make suitable SiNWs. As will also be appreciated by those skilled in the art, these teachings can be adopted for growing other nanomaterials on catalytically active substrates, including carbon nanotube growth, whether the substrates are oriented horizontally, vertically or in any other orientation. Extensions of these component designs and process conditions, as well as derivations thereof, are intended to be included in this disclosure.

1. A chemical vapor processing reactor comprising:
a horizontal reaction tube enclosed within an external heater;
a preheater positioned within the reaction tube, the preheater including a plurality of baffles that collectively define a tortuous gas transmission path through the preheater;
a round-to-rectangular flow converter configured to convert gas flowing from the preheater into a rectangular flow;
one or more substrates suitable for nanomaterial growth positioned within the flow converter; and
an exhaust gas collector to remove gas exiting from the flow converter.

2. The chemical vapor processing reactor of claim 1 wherein each baffle of the plurality of baffles includes at least one internal cutout for gas transmission that allows process gas and heat radiation to pass between two adjacent baffles of the plurality of baffles, the internal cutouts collectively defining the tortuous gas transmission path through the preheater.

3. The chemical vapor processing reactor of claim 1 wherein the flow converter includes an H-bridge.

4. The chemical vapor processing reactor of claim 1 wherein the flow converter includes a double H-bridge.

5. The chemical vapor processing reactor of claim 1 wherein the flow converter includes a first converter baffle having a rectangular opening, a second converter baffle having a rectangular opening, and a pair of parallel walls connecting the first and second converter baffles.

6. The chemical vapor processing reactor of claim 1 wherein the one or more substrates is suitable for SiNW growth.

7. The chemical vapor processing reactor of claim 1 wherein the one or more substrates is suitable for carbon nanotube growth.

8. The chemical vapor processing reactor of claim 1 wherein the one or more substrates includes at least one catalytically active substrate.

9. The chemical vapor processing reactor of claim 8 wherein the at least one catalytically active substrate includes a Si wafer covered with spatially isolated catalytic nanoparticles.

10. The chemical vapor processing reactor of claim 9 wherein the catalytic nanoparticles include gold, copper, or copper oxide nanoparticles.

11. A chemical vapor processing reactor comprising:
a horizontal reaction tube enclosed within an external heater;
a round-to-rectangular flow converter configured to convert gas flowing from the preheater into a rectangular flow through a vertically oriented opening;
one or more vertically oriented substrates suitable for nanomaterial growth positioned within the flow converter; and
an exhaust gas collector to remove gas exiting from the flow converter.

12. The chemical vapor processing reactor of claim 11 wherein the flow converter includes two baffles joined together by two planar walls.

13. The chemical vapor processing reactor of claim 11 wherein the one or more vertically oriented substrates includes a plurality of catalytically active foils or mesh structures.

14. The chemical vapor processing reactor of claim 11 further including a preheater positioned within the reaction tube, the preheater including a plurality of baffles that collectively define a tortuous gas transmission path through the preheater.

15. Harvestable silicon nanowires (SiNWs) grown on a catalytically active growth substrate with a diameter greater than four inches, the catalytically active substrate comprising catalytic nanoparticles having a diameter, the SiNWs having an average diameter less than 1.5 times the diameter of the catalytic nanoparticles, a length greater than 5 μm, a diameter distribution not greater than 50% of the diameter of the catalytic nanoparticles, and an average resistance of from 0.01 to 100 MΩ.

16. The chemical vapor processing reactor of claim 1 wherein the external heater is configured to heat the plurality of baffles and the one or more substrates by convection and radiation absorption.

17. The chemical vapor processing reactor of claim 1 wherein the external heater includes resistive furnace elements.

18. The chemical vapor processing reactor of claim 1 wherein the external heater is a rolling furnace.

19. The chemical vapor processing reactor of claim 11 wherein the external heater includes resistive furnace elements configured to heat the one or more vertically oriented substrates by convection and radiation absorption.

20. The chemical vapor processing reactor of claim 13 wherein the one or more vertically oriented substrates includes a plurality of catalytically active foils configured for the growth of carbon nanotubes.
